(19) United States
(12) Patent Application Publication
(10) Pub. No.: US 2010/0240190 A1
(43) Pub. Date: Sep. 23, 2010

(54) METHOD FOR FABRICATING DEEP TRENCH CAPACITOR

(75) Inventor: YUNG-CHANG LIN, Taichung County (TW)

Correspondence Address: J C PATENTS, 4 VENTURE, SUITE 250, IRVINE, CA, 92618, US

(73) Assignee: United Microelectronics Corp., Hsinchu (TW)

(21) Appl. No.: 12/407,509

(22) Filed: Mar. 19, 2009

(51) Int. Cl. H01L 21/02

(52) U.S. Cl. 438/386; 257/E21.008

(57) ABSTRACT

A method for fabricating the deep trench capacitor is described as follows. A substrate of a first conductivity type is provided, which includes a deep band region of a second conductivity type therein. A deep trench is formed in the substrate and through the deep band region. A collar oxide is then formed in an upper portion of the trench, wherein at least a portion of the deep band region is exposed. A bottom electrode, a capacitor dielectric layer and a top electrode are formed in the trench sequentially.

### BACKGROUND OF THE INVENTION

1. Field of the Invention

The present invention relates to a method for fabricating a memory capacitor, and more particularly, to a method for fabricating a deep trench capacitor.

2. Description of Related Art

Along with rapid progress of semiconductor technology, the dimensions of semiconductor devices are reduced and the integrity thereof promoted continuously to further advance the operating speed and performance of the integrated circuit. As for memory components having capacitors, the size reducing means the available space used for fabricating capacitors become smaller and smaller, as the demand for device integrity is raised. Hence, how to make capacitors with sufficient capacity and good performance has to be considered in the recent semiconductor technology.

Generally, there are a lot of methods for increasing the charge storage capacity of capacitors, such as a deep trench capacitor. The design of the deep trench capacitor is a method for fabricating capacitors by using the spaces in the substrate to increase the charge storage area. FIGS. 1A-1B are schematic cross-sectional views illustrating a conventional fabrication process of a deep trench for accommodating a deep trench capacitor. As shown in FIG. 1A, a trench 106a is formed in a substrate 100 using a hard mask layer 104 as an etching mask. The depth of the trench 106a is substantially within a range of a deep band region 102 which is formed in the substrate 100. In other words, the bottom of the trench 106a is located in the deep band region 102. A conformal collar oxide 108 is then deposited on the surface of the trench 106a.

As shown in FIG. 1B, a portion of the collar oxide 108 located in the bottom of the trench 106a is removed, such that the remaining collar oxide 108a is disposed on the sidewall of the trench 106a. A portion of the substrate 100 is then etched using the remaining collar oxide 108a as a mask, so as to form a trench 106b. A bump (not shown), however, may be formed at the interface of the trench 106a and the trench 106b, and the deep trench including the trench 106a and 106b may suffer from a poor profile. Moreover, the trench 106b is formed using the thick collar oxide 108a as the mask, and therefore, the critical dimension of the capacitor subsequently-formed in the deep trench has a limitation in miniaturization, which may make a great impact on the performance of the device.

### SUMMARY OF THE INVENTION

Accordingly, the present invention is directed to a method for fabricating a deep trench capacitor, in which the deep trench can have a smooth and better profile.

The method for fabricating the deep trench capacitor of the present invention is described as follows. A substrate of a first conductivity type is provided, which includes a deep band region of a second conductivity type therein. A deep trench is formed in the substrate and through the deep band region. A collar oxide is then formed in an upper portion of the trench, wherein at least a portion of the deep band region is exposed. A bottom electrode, a capacitor dielectric layer and a top electrode are formed in the trench sequentially.

According to an embodiment of the present invention, a method for forming the collar oxide may include following steps. A mask layer is formed in a lower portion of the trench so that a portion of the deep band region is exposed, wherein the mask layer has an etching selectivity different from an etching selectivity of the collar oxide. An oxide layer is formed on a surface of the trench using the mask layer as a mask. The mask layer is then removed.

According to an embodiment of the present invention, a method for forming the oxide layer can be a thermal oxidation process.

According to an embodiment of the present invention, a method for forming the mask layer includes following steps. A mask material layer is formed conformally on the surface of the trench. A photoresist layer is formed in the lower portion of the trench. A portion of the mask material layer is removed using the photoresist layer as a mask, followed by removing the photoresist layer.

According to an embodiment of the present invention, the material of the mask layer may be silicon nitride.

According to an embodiment of the present invention, a method for forming the bottom electrode may include following steps. A conductive layer is formed conformally on the surface of the trench. A photoresist layer is formed in the trench, wherein a top surface of the photoresist layer is lower than a top surface of the substrate. A portion of the conductive layer is removed using the photoresist layer as a mask, and the photoresist layer is then removed.

According to an embodiment of the present invention, a method for forming the capacitor dielectric layer can be carried out by conformally forming a silicon nitride layer on the surface of the trench and then conformally forming a silicon oxide layer on the silicon nitride layer.

According to an embodiment of the present invention, a method for forming the top electrode may include filling up the trench with a conductive layer, and removing a portion of the conductive layer such that a top surface of the conductive layer is substantially equal to a top surface of the substrate.

According to an embodiment of the present invention, an isolation structure is further formed in the substrate before the deep trench is formed. The isolation structure is a shallow trench isolation (STI) structure, for example.

According to an embodiment of the present invention, a well region of the first conductivity type is formed in the substrate, wherein the deep band region is formed under the well region.

According to an embodiment of the present invention, a method for forming the deep trench can be conducted by a single etching process.

According to an embodiment of the present invention, a depth of the deep trench is within a range of 2.0 μm to 8.0 μm.

According to an embodiment of the present invention, the bottom electrode may be doped polysilicon, the capacitor dielectric layer may be silicon oxide/silicon nitride/silicon nitride (ONO), and the top electrode may be doped polysilicon.

According to an embodiment of the present invention, the first conductivity type is P-type and the second conductivity is N-type or, in the alternative, the first conductivity type is N-type and the second conductivity is P-type.

As mentioned above, the method for fabricating the deep trench capacitor in the present invention is implemented by conducting a single etching process to form the deep trench in the substrate. Since the deep trench is formed through the deep band region in a single etching process, the profile of the deep trench is smooth and superior after the collar oxide is formed on the upper portion of the trench.

Further, the hard mask layer is utilized in the formation of the deep trench, such that the profile of the deep trench can be easily controlled and the dimensions of the capacitor formed in the deep trench can be effectively miniaturized. Accordingly, the method for fabricating the deep trench capacitor in the present invention is simplified.

In order to make the aforementioned and other features and advantages of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1B are schematic cross-sectional views illustrating a conventional fabrication process of a deep trench for the deep trench capacitor.

FIGS. 2A-2G depict, in a cross-sectional view, a method for fabricating a deep trench capacitor according to an embodiment of the present invention.

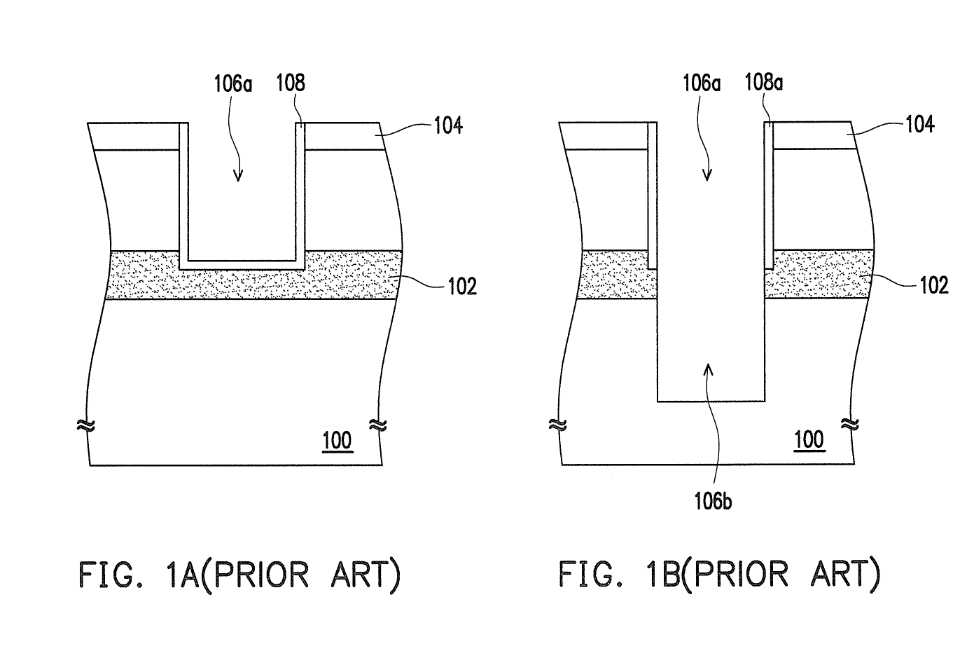

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

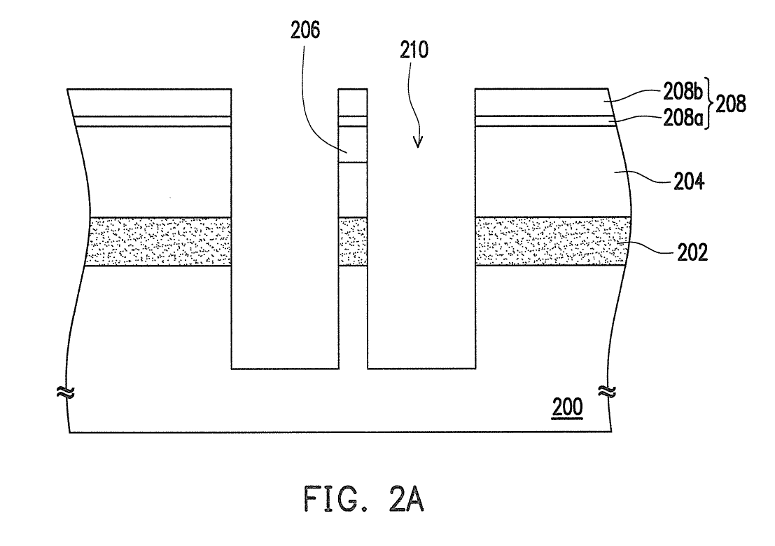

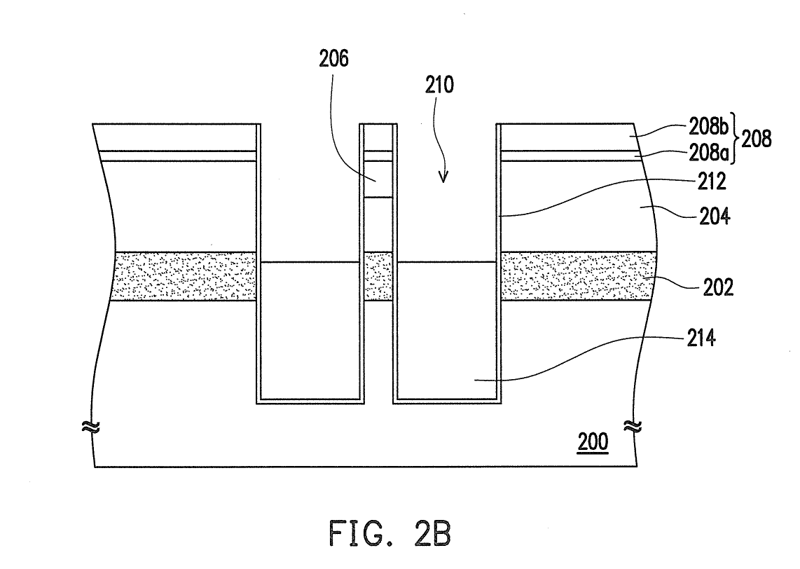

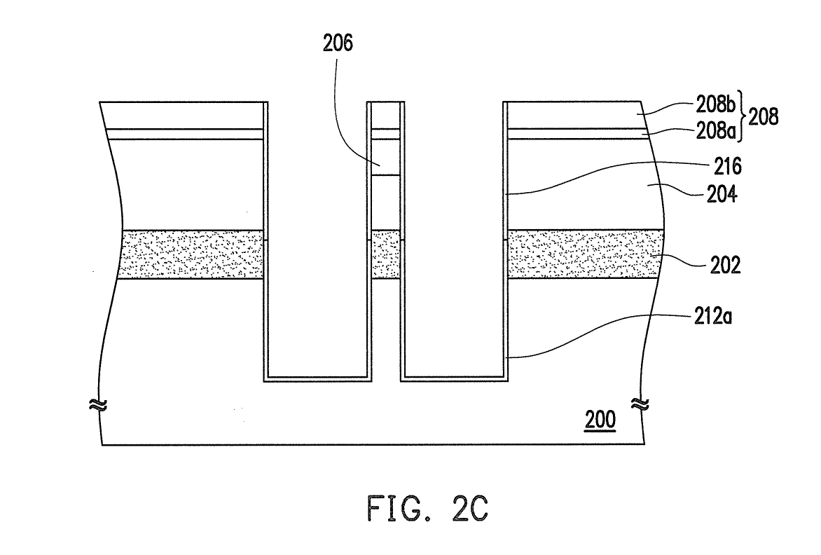

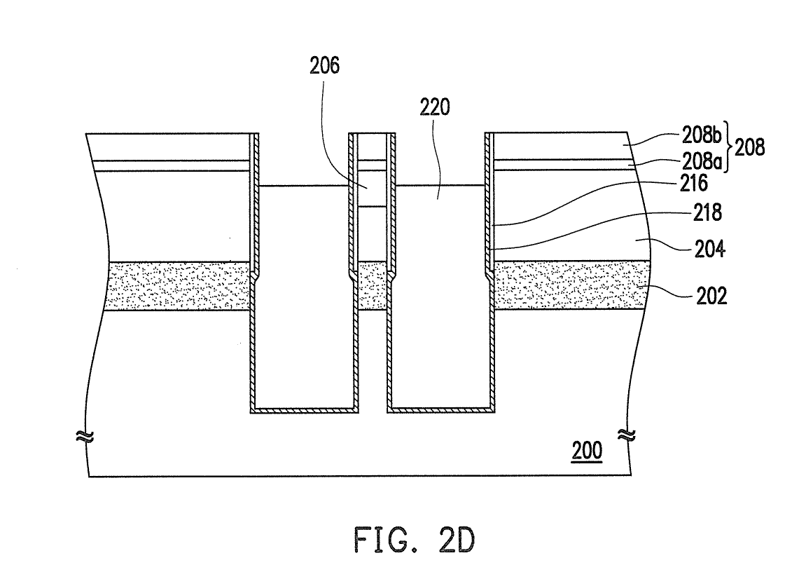

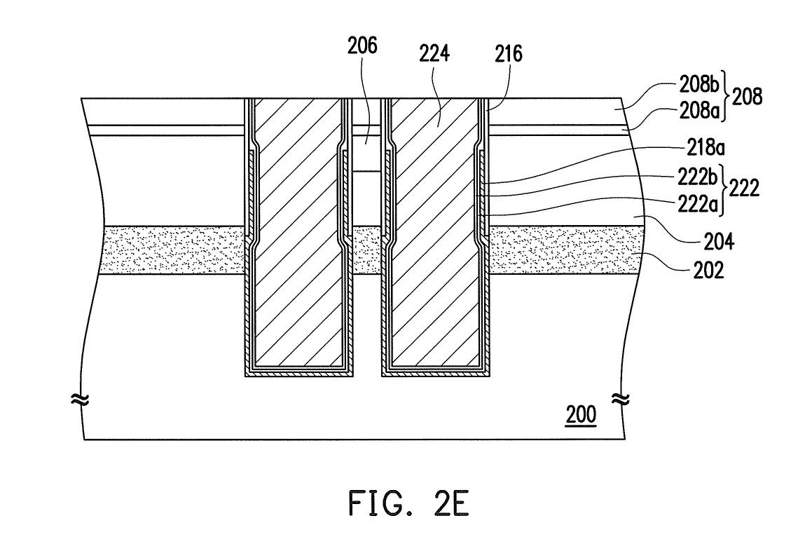

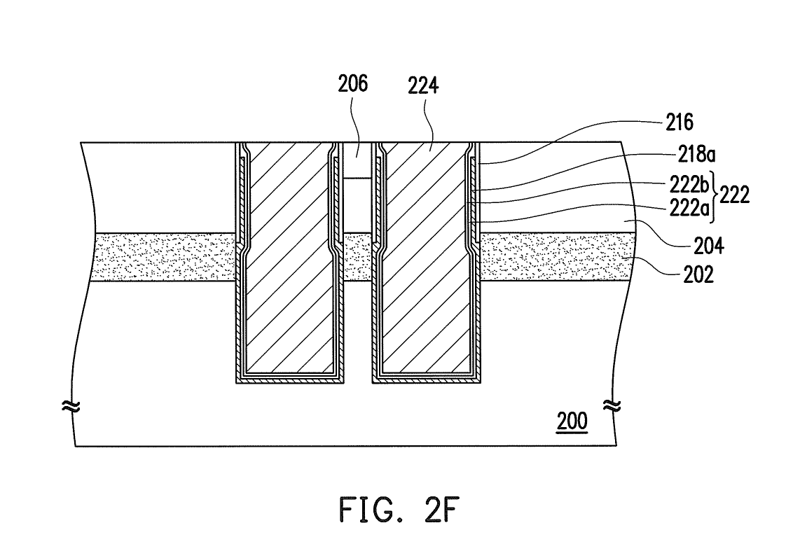

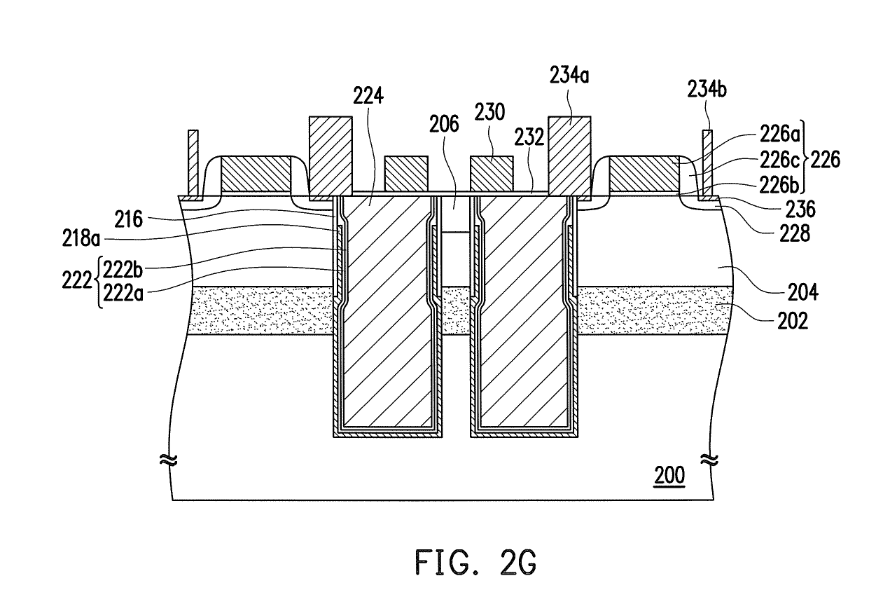

FIGS. 2A-2G depict, in a cross-sectional view, a method for fabricating a deep trench capacitor according to an embodiment of the present invention. It is noted that the following embodiment in which the first conductivity type is P-type and the second conductivity type is N-type is provided for illustration purposes, and should not be construed as limiting the scope of the present invention. It is appreciated by persons skilled in the art that the first conductivity type can be N-type and the second conductivity type can be P-type.

Referring to FIG. 2A, a substrate 200 of a first conductivity type is provided, which may be a P-type silicon substrate. A deep band region 202 of a second conductivity type and a well region 204 of the first conductivity type are formed in the substrate 200, wherein the deep band region 202 may be a deep N-band and the well region 204 may be a P-well. The deep band region 202 is, for example, disposed underneath the well region 204. In an embodiment, an isolation structure 206 is formed in the substrate 200. The isolation structure 206 can be a shallow trench isolation (STI) structure. A patterned hard mask layer 208 is formed on the substrate 200. The method for forming the patterned hard mask layer 208 including forming a silicon nitride layer 208a and a silicon oxide layer 208b in sequence on the substrate 200, and then a patterned trench mask (not shown) is formed to remove a portion of the silicon nitride layer 208a and the silicon oxide layer 208b so as to reveal a portion of the substrate 200. In an embodiment, the material of the patterned trench mask can be photoresist. Afterwards, a portion of the substrate 200 is removed using the patterned trench mask as a mask, so as to form deep trenches 210. The deep trenches 210 break through the deep band region 202. That is to say, the depth of each deep trench 210 is deeper than that of the deep band region 202. The depth of each deep trench 210 can be within a range of 2.0 μm to 8.0 μm. The method for forming the deep trenches 210 may include only a single etching process. After the deep trench 210 is formed, the patterned trench mask is removed.

Referring to FIG. 2B, a mask material layer 212 is formed conformally on the surface of each trench 210. The mask material layer 212 can be a material having an etching selectivity different from that of the subsequently-formed collar oxide. In an embodiment, the material of the mask material layer 212 can be silicon nitride. A photoresist layer 214 is formed in the lower portion of the trenches 210. The formation of the photoresist layer 214 can be implemented by filling the trenches 210 with a photoresist material and then etching back a portion of the photoresist material. The top surface of the photoresist layer 214 is lower than the upper edge of the deep band region 202 and higher than the lower edge of the deep band region 202, such that a portion of the deep band region 202 is not overlaid by the photoresist layer 214.

Referring to FIG. 2C, a portion of the mask material layer 212 is removed using the photoresist layer 214 as a mask, so as to form the mask layer 212a. The method for removing a portion of the mask material layer 212 can be a dry etching process or a wet etching process. In an embodiment, a portion of the mask material layer 212 may be removed using heated phosphoric acid. After the mask layer 212a is formed, the photoresist layer 214 is removed. The mask layer 212a covers the lower portion of the trenches 210, and a portion of the deep band region 202 is exposed. An oxide layer is formed conformally on the surface of each trench 210 using the mask layer 212a as a mask, so as to form a collar oxide 216 in the upper portion of each trench 210. The formation of the collar oxide 216 can be carried out by conducting a thermal oxidation process.

Referring to FIG. 2D, the mask layer 212a is removed, so that the surface of the trenches 210 at the lower portion and a portion of the deep band region 202 are uncovered. The removal of the mask layer 212a can be implemented by a dry etching process or by a wet etching process using heated phosphoric acid. Since the deep trenches 210 are formed in a single etching process and the collar oxide 216 then covers the upper portion of the trenches 210, the interface between the collar oxide 216 and the deep band region 202 has a smooth and a better profile. Afterwards, a conductive layer 218 is formed conformally on the surface of each trench 210. The material of the conductive layer 218 may be doped polysilicon. The method used for fabricating the conductive layer 218 includes, for example, first performing a chemical vapor deposition (CVD) process to form an undoped polysilicon layer, followed by performing an ion implantation process to dope the polysilicon layer; or, in the alternative, performing a CVD process with an in-situ dopant implantation to form a doped polysilicon layer. A photoresist layer 220 is then formed in the trenches 210. The formation of the photoresist layer 220 can be implemented by filling the trenches 210 with a photoresist material and then etching back a portion of the photoresist material. The top surface of the photoresist layer 220, for example, is lower than that of the substrate 200, and accordingly a portion of the conductive layer 218 is exposed. The interval between the top surface of the photoresist layer 220 and the top surface of the substrate 200 may be about 1000-3000 Å.

Referring to FIG. 2E, a portion of the conductive layer 218 is removed using the photoresist layer 220 as a mask, so as to form a bottom electrode 218a. The method for removing a portion of the conductive layer 218 may be a dry etching process. After the bottom electrode 218a is formed, the photoresist layer 220 is removed. The bottom electrode 218a covers the surface of the trenches 210 and a portion of the collar oxide 216 conformally. Thereupon, a capacitor dielectric layer 222 is formed on the surface of each trench 210. The material of the capacitor dielectric layer 222 may be a combination of silicon oxide/silicon nitride/silicon nitride (ONO). In an embodiment, a native oxide (not shown) may be formed over the surface of each trench 210, and a silicon nitride layer 222a and a silicon oxide layer 222b are deposited sequentially over the native oxide so as to form the capacitor dielectric layer 222. Afterwards, a conductive layer 224 which fills up the trenches 210 is formed on the substrate 200. The material of the conductive layer 224 may be doped polysilicon. In an embodiment, the conductive layer 224 may be formed on the mask layer 208, and a chemical mechanical polishing (CMP) process is then conducted using the mask layer 208 as a polishing stop layer so as to remove partial conductive layer 224.

Referring to FIG. 2F, the conductive layer 224 in the trenches 210 may be further etched back, such that the top surface of the conductive layer 224 is substantially equal to that of the substrate 200. Thereafter, the mask layer 208 is removed and the surface of the substrate 200 is exposed, so as to accomplish the fabrication of the deep trench capacitor.

In addition, a series of logic process, such as the formation of oxide layer, polysilicon layer, spacers, contacts and interconnection, can be conducted to complete the fabrication of embedded dynamic random access memory (eDRAM). As shown in FIG. 2G, in an embodiment, gate structures 226, polysilicon layers 230 serving as bits, an oxide layer 232, share contacts 234a, and contacts 234b serving as bit lines are formed on the substrate 200, and doping regions 228 are formed in the substrate 200 at both sides of the gate structures 226. Each gate structure 226, for example, includes a poly gate 226a serving as a word line, a gate oxide 226b disposed between the poly gate 226a and the substrate 200, and spacers 226c disposed on the sidewalls of the poly gate 226a. A salicide layer 236 can further be formed between the share contacts 234a and the doping regions 228, or between the contacts 234b and the doping regions 228. It is noted that the forming methods and forming sequences of the above-mentioned components, i.e. the logic process, are well appreciated by persons skilled in the art, and thus, the detailed descriptions thereof are not described herein.

In view of the above, the substrate is etched through the deep band region to form the deep trench in a single etching process according to the method of the present invention. Therefore, after the collar oxide is formed on the upper portion of the deep trench, a smooth profile without bumps can still remain in the deep trench. In addition, the profile of the deep trench is prone to be controlled and the dimensions thereof can be easily miniaturized owing to the single etching process.

Moreover, the method for fabricating the deep trench capacitor in the present invention relies on a single etching process through the modification of the deep trench formation, so as to easily be incorporated into the current process. Hence, not only the process is simplified without raising the cost, the profile of the deep trench can be more effectively improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a deep trench capacitor, comprising:
providing a substrate of a first conductivity type, comprising a deep band region of a second conductivity type therein;
forming a deep trench in the substrate and through the deep band region;
forming a collar oxide in an upper portion of the trench, wherein at least a portion of the deep band region is exposed; and
forming a bottom electrode, a capacitor dielectric layer and a top electrode in the trench sequentially.

2. The method according to claim 1, wherein a method for forming the collar oxide comprises:
forming a mask layer in a lower portion of the trench so that a portion of the deep band region is exposed, wherein the mask layer has an etching selectivity different from an etching selectivity of the collar oxide;
forming an oxide layer on a surface of the trench using the mask layer as a mask; and
removing the mask layer.

3. The method according to claim 2, wherein a method for forming the oxide layer comprises a thermal oxidation process.

4. The method according to claim 2, wherein a method for forming the mask layer comprises:
conformally forming a mask material layer on the surface of the trench;
forming a photoresist layer in the lower portion of the trench;
removing a portion of the mask material layer using the photoresist layer as a mask; and
removing the photoresist layer.

5. The method according to claim 2, wherein the mask layer comprises silicon nitride.

6. The method according to claim 1, wherein a method for forming the bottom electrode comprises:
conformally forming a conductive layer on the surface of the trench;
forming a photoresist layer in the trench, wherein a top surface of the photoresist layer is lower than a top surface of the substrate;
removing a portion of the conductive layer using the photoresist layer as a mask; and
removing the photoresist layer.

7. The method according to claim 1, wherein a method for forming the capacitor dielectric layer comprises:
conformally forming a silicon nitride layer on the surface of the trench; and
conformally forming a silicon oxide layer on the silicon nitride layer.

8. The method according to claim 1, wherein a method for forming the top electrode comprises:
filling up the trench with a conductive layer; and
removing a portion of the conductive layer, such that a top surface of the conductive layer is substantially equal to a top surface of the substrate.

9. The method according to claim 1, before the deep trench is formed further comprising forming an isolation structure in the substrate.

10. The method according to claim 9, wherein the isolation structure comprises a shallow trench isolation (STI) structure.

11. The method according to claim 1, further comprising forming a well region of the first conductivity type in the substrate, wherein the deep band region is formed under the well region.

12. The method according to claim 1, wherein a method for forming the deep trench comprises a single etching process.

13. The method according to claim 1, wherein a depth of the deep trench is within a range of 2.0 μm to 8.0 μm.

14. The method according to claim 1, wherein the bottom electrode comprises doped polysilicon.

15. The method according to claim 1, wherein the capacitor dielectric layer comprises silicon oxide/silicon nitride/silicon nitride (ONO).

16. The method according to claim 1, wherein the top electrode comprises doped polysilicon.

17. The method according to claim 1, wherein the first conductivity type is P-type and the second conductivity is N-type.

18. The method according to claim 1, wherein the first conductivity type is N-type and the second conductivity is P-type.
